(19) United States
(12) Patent Application Publication
(10) Pub. No.: US 2023/0176115 A1
(43) Pub. Date: Jun. 8, 2023

(54) LOCALIZED MAGNETIC FIELD TESTING

(71) Applicant: International Business Machines Corporation, Armonk, NY (US)

(72) Inventors: Kushagra Sinha, Wappingers Falls, NY (US); Pablo Nieves, Pinebluff, NY (US); Reinaldo Vega, Mahopac, NY (US)

(21) Appl. No.: 17/540,835

(22) Filed: Dec. 2, 2021

(51) Int. Cl. G01R 31/28

(52) U.S. Cl. CPC G01R 31/2891; G01R 31/2889

(57) ABSTRACT

A testing apparatus comprises a first electromagnet. The first electromagnet can be configured to expose a first test device to a first electromagnetic field. The testing apparatus also comprises a second electromagnet. The second electromagnet can be configured to expose a second test device to a second electromagnetic field.

### BACKGROUND

The present invention relates to testing electronic devices, and more specifically, to testing on-wafer device functionality using magnetic fields.

Electronic devices, such as memory and transistor structures, capacitors, resistors, and others are sometimes tested before being assembled into a finished product or sold. Some surface-mount devices, such as surface-mount capacitors, can sometimes be tested by contacting the electrical contacts to which those surface-mount devices are attached with a pair of electrical probes.

However, some surface-mount devices and some embedded devices, such as magnetic memory structures and antennas, require testing with magnetic fields, rather than direct electrical contact. These structures are often tested by detecting the response of the device to the exposure of a permanent magnet placed near the device (e.g., above a wafer that contains the device).

### SUMMARY

Some embodiments of the present disclosure can be illustrated as a testing apparatus that comprises a first electromagnet. The first electromagnet is configured to expose a first test device to a first electromagnetic field. The testing apparatus also comprises a second electromagnet. The second electromagnet is configured to expose a second test device to a second electromagnetic field.

Some embodiments of the present disclosure can also be illustrated as a processor and a memory in communication with the processor. The memory contains program instructions that, when executed by the processor, are configured to cause the processor to perform a method. The method comprises identifying a testing requirement of a device. The testing requirement comprises a property of a magnetic field. The method also comprises selecting a required position of an electromagnet in the testing-apparatus system based on the property. The required position is selected to expose the device to a magnetic field that has the property. The method also comprises shifting an electromagnetic to the required position in the testing-apparatus system. The method also comprises selecting a required current of the electromagnet. The current is selected to expose the device to the magnetic field that has the property. The method also comprises inducing the current in the electromagnet.

Some embodiments of the present disclosure can also be illustrated as a testing apparatus comprising a first track and a second track mounted on the first track. The second track is oriented orthogonally to the first track and is capable of translating on the first track. The testing apparatus also comprises an attachment point mounted on the second track. The attachment point is configured to translate on the second track. The testing apparatus also comprises an electromagnet mounted to the attachment point, such that translating the second track throughout the first track and translating the attachment point throughout the second track causes the electromagnet to change position in the testing apparatus. Inducing a current in the electromagnet causes the electromagnet to create a magnetic field in the testing apparatus.

### BRIEF DESCRIPTION OF THE DRAWINGS

FIG. 1A illustrates a top-down view of an apparatus configured to test the effect of a magnetic field on a device with a solenoid coil and a magnetic field on a device with a wire.

FIG. 1B illustrates a side view of the apparatus configured to test the effect of a magnetic field on a device with the solenoid coil and an in-plane magnetic field on a device with the wire.

FIG. 2 illustrates a side view of an apparatus configured to test the effect of a magnetic field on a device with a rotated solenoid coil and a magnetic field on a device with an out-of-plane wire.

FIG. 3 illustrates a top-down view of an apparatus configured to test the effect of multiple distinct magnetic fields on a set of devices using wires of different thicknesses.

FIG. 4 illustrates a top-down view of an apparatus that comprises solenoid coils of different turn density.

FIG. 5A illustrates a top-down view of an apparatus configured to test four devices with an current-carrying closed-loop wire.

FIG. 5B illustrates a side view of the apparatus configured to test four devices with the current-carrying closed-loop wire.

FIG. 6A illustrates a top-down view of an apparatus configured to test four devices with a 6-turn solenoid coil and a wire.

FIG. 6B illustrates a side view of the apparatus configured to test four devices four devices with a 6-turn solenoid coil and a wire.

FIG. 7 depicts a method 700 of adjusting a test apparatus based on a testing requirement of a device in the test apparatus.

FIG. 8 illustrates an example set of tracks by which an electromagnet may be relocated in a test apparatus.

FIG. 9 depicts the representative major components of a computer system that may be used in a test apparatus in accordance with embodiments.

### DETAILED DESCRIPTION

Electrical-device testing is a process of measuring the response of devices under test to target stimuli. This often takes the form of applying a voltage across the device by touching electrical probes to contact points on the electrical device. This may be common, for example, when testing circuits between two or more vias in a circuit board, testing surface-mount capacitors, surface-mount resistors, or others. However, in order to test the functionality of some devices, the response of those devices to an external magnetic field is measured. For example, testing the proper functionality of a magnetic RAM cell within a wafer may require subjecting that magnetic RAM cell to magnetic field lines of a specific direction and strength. Further, testing the functionality of an antenna within or on a circuit board may require testing the ability of the antenna to transmit intended signals in the presence of magnetic field lines of various strengths and directions. Indeed, almost any electrical devices (e.g., flash memory, capacitors) may require testing for proper functionality in the presence of a magnetic field depending on the use case of the device.

Typical test apparatuses for devices that require magnetic-field testing include a stationary permanent magnet or electrical magnet that is capable of applying a magnetic field to the entire test apparatus. In other words, typical apparatuses operate by applying a magnetic field to all devices within the apparatus. While this may, in some use cases, result in an ability to efficiently test many devices in an apparatus in a relatively short amount of time, it also can result in a difficulty to control the exposure of sensitive devices to the magnetic field. For example, the performance of some devices in a substrate board may be affected by the magnetic field in a negative, unintended way.

In some use cases, a substrate may not contain any devices that are negatively affected by the magnetic field of a typical test apparatus. However, these substrates may still contain devices that require testing at specific magnetic field strengths. Unfortunately, the relative strength of the magnetic field throughout a typical test apparatus is often not precisely controllable. For example, in some test apparatuses a permanent magnet may be located above the center of a test apparatus. A wafer may be inserted into the test apparatus for testing such that a first device is directly below the center of the magnet and a second device is located at the edge of the test apparatus.

If these two devices require the testing with the same magnetic field strength, testing both devices at once may be very difficult due to the difference in distance between each device and the magnet. Further, if the second device actually requires a testing with a stronger magnetic field than the first device, the test apparatus must be large enough to position the second device, which may be at the edge of the wafer, nearer to the magnet than the first device, which may be at the center of the wafer. This may require the test apparatus to be significantly larger than would otherwise be necessary.

Further, the relative direction of this magnetic field within typical test apparatuses is oftentimes static. In other words, to test the effect of a magnetic field line of a particular direction on a device, the substrate that contains that device must be oriented in a specific way such that the device is located within the magnetic field at a point at which the field lines run in that particular direction. For example, there may be a first device within a wafer that requires testing in the presence of field lines in a first direction and a second device in the wafer that requires testing in the presence of field lines in a second directly. Testing both these devices may require positioning and orienting the wafer in the test apparatus to test the first device, then repositioning and reorienting the wafer in the test apparatus to test the second device. Not only may this extend testing time, but it may also require the test apparatus to be large enough to accommodate the wafer in a variety of positions and orientations. Again, this may require the test apparatus to be significantly larger than would otherwise be necessary.

Finally, even when applying a magnetic field throughout the test apparatus to test all devices does not negatively impact any test device in the apparatus, applying a magnetic field strong enough to test devices throughout the apparatus may negatively affect the performance of test-apparatus components within the test apparatus. For example, some test apparatuses include electrical probes that are designed to detect reactions of the test devices to exposure to magnetic fields. These probes often are ferromagnetic themselves, meaning that they also respond to the magnetic field of the test apparatus. Applying a magnetic field throughout the test apparatus may cause some of these probes to move in response to the magnetic field. This may impact the ability of the probes to accurately detect the response of the test devices to the magnetic field. In some instances, this may result in multiple test devices that respond identically to the magnetic field actually being measured as responding inconsistently to the magnetic field. In other instances, this may result in some probes being completely unable to measure the response of a device to the magnetic field. In extreme cases, the probes may themselves be damaged by the exposure to the magnetic field, or may cause damage to the test substrate. For example, the tip of a probe may, when exposed to a magnetic field, be pushed into a contact pad on a substrate in a way that bends the probe or damages the contact pad. This may cause the probe to become non-functional in the current or future tests, and may cause the contact pad on the substrate to become non functional as well.

Some embodiments of the present disclosure address the above issues by incorporating customizable electromagnets into a test apparatus. These customizable electromagnets may be designed to apply a magnetic field to only a portion of a test apparatus, rather than an entire test apparatus.

For example, some embodiments of the present disclosure may incorporate a test apparatus that comprises a set of solenoid coils. The turn density of and current flowing through these solenoid coils may be adjusted to adjust the strength of the magnetic field near the coils. For example, a solenoid coil with 3 turns within a centimeter may be placed above a device that requires testing with a weak magnetic field, whereas a solenoid coil with 20 turns within a centimeter may be placed above a device that requires testing with a strong magnetic field. Further, the orientation of each solenoid coil may be adjusted to apply fields lines to each device according to the testing needs of that device.

Some embodiments of the present disclosure may also incorporate a test apparatus that comprises a set of straight wires. The current flowing through these wires, as well as the distance between the wires and the devices under test may be adjusted to adjust the strength of the magnetic field at those devices under test. For example, a first wire carrying high current may be placed near a first device that requires testing with a strong magnetic field, and a second wire carrying lower current may be placed farther away from a second device that requires testing with a weaker magnetic field.

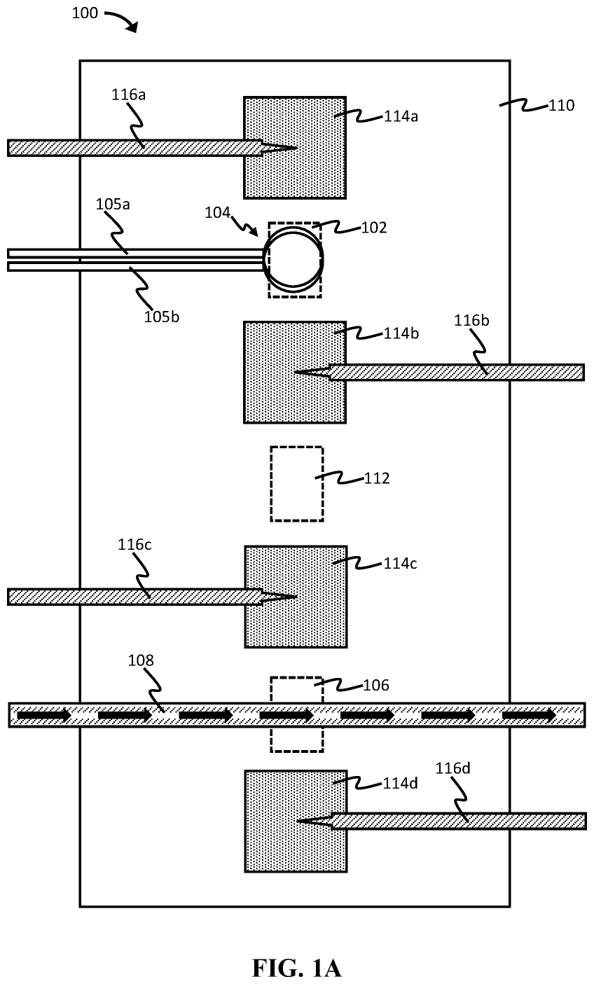

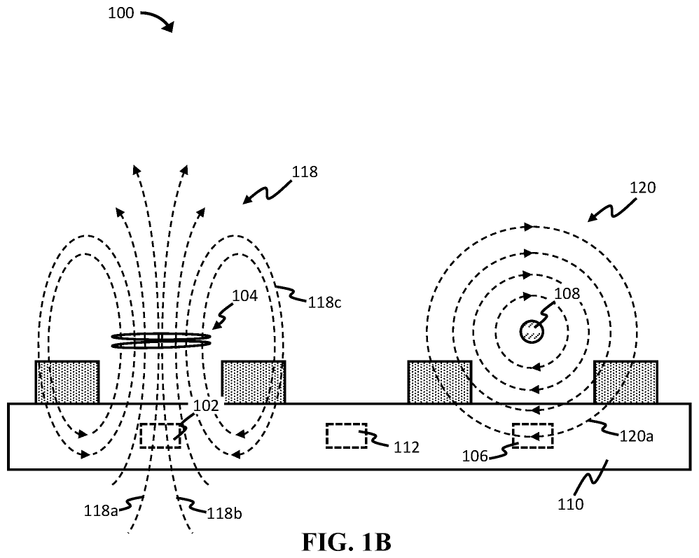

For example, FIG. 1A illustrates a top-down view of an apparatus 100 configured to test a device 102 with a solenoid coil 104 and a device 106 with a wire 108 (sometimes referred to herein as simply “wire 108”). Devices 102 and 106 are illustrated as embedded within substrate 110, which has been placed within apparatus 100 for testing purposes. Substrate 110 may be, for example, a silicon wafer or a circuit board composed of layers of silicon, wire, and resin. Apparatus 100 contains contact pads 114a-114d and testing probes 116a-116d. Contact pads 114a-114d may be electrically connected (for example, with conductive wires) to terminals on wafer 110 that are themselves connected to the magnetic devices therein. Testing probes 116a-116d may be designed to touch contact pads 114a-114d to detect electrical signals originating from the magnetic devices within substrate 110.

For example, contact pad 114a may be connected to a terminal, which itself may be connected to device 102 through wiring within substrate 110. Through this connection, probe 116a may be able to detect the response of device 102 to an external magnetic field. In another example, separate connections to two device terminals may be necessary to properly test the response of device 102 to an external magnetic field. In this example, contact pad 114a may be connected to a first terminal, and contact pad 114b may be connected to a terminal. Together, probes 116a and 116b may then be used to measure the response of device 102. Of note, the number and form of contact pads 114a-114d and of testing probes 116a-116d illustrated in FIG. 1A and other figures of the present disclosure are meant to be examples only for the sake of understanding. The precise number, locations, form, and other properties of the contact pads and testing probes in testing apparatuses may vary while still remaining within the spirit of the embodiments of the present disclosure.

In addition to devices 102 and 106, substrate 110 also contains sensitive device 112. Sensitive device 112 may not require magnetic testing, and may even be damaged by the magnetic fields required to test devices 102 and 106, if placed in sufficiently close proximity to the sources of those magnetic fields.

To avoid damage to device 112 when applying an electromagnetic field to test devices 102 and 106 (the “devices under test”), electromagnets are placed in near proximity to devices 102 and 106. These electromagnets may be more configurable than one or more large magnets that, together, apply a larger magnetic field throughout apparatus 100. As a result, magnetic fields of the desired strength and orientation may be applied to devices 102 and 106 without applying a significant magnetic field at device 112.

For example, by causing current to flow through solenoid 104 (for example, by connecting solenoid 104 to an external voltage source or current source), a magnetic field will be applied around solenoid 104, with some field lines oriented directly down into device 102. This current could be applied to the coil 104, for example, through solenoid support arms 105a and 105b. Solenoid support arms 105a and 105b may provide a structural attachment between solenoid coil 104 to apparatus 100, and may themselves be conductive or may take the form of an insulative sheath/sleeve that contain conductive material such as a wire. Further, by causing current to flow through wire 108, a magnetic field will be applied around wire 108, with field lines orbiting wire 108 in concentric circles. In FIG. 1A, the direction of this current is illustrated by within wire 108.

FIG. 1B illustrates a side view of apparatus 100 and illustrates the field lines of the magnetic fields created by solenoid 104 and wire 108. Magnetic field lines 118 result from current flowing through solenoid coil 104, and magnetic field lines 120 result from current flowing through wire 108.

As illustrated by FIG. 1B, each of devices 102 and 106 is exposed to a magnetic field for testing, but sensitive device 112 is not significantly exposed to a magnetic field. This may prevent potential damage to sensitive device 112 during testing of devices 102 and 106. While, in theory, sensitive device may always be exposed to some level of magnetic field, the magnetic fields of solenoid 104 and wire 108 may be localized enough that they are negligible at device 112.

FIG. 1B also depicts one example of the configurability of apparatus 100. Magnetic field lines 118a and 118b are illustrated as passing directly through device 102 in a mostly vertical direction. However, magnetic field line 120a is illustrated as passing directly through device 106 in a mostly horizontal direction. In other words, apparatus 100 discloses the ability to vary the direction of the magnetic field lines at a device by varying the form of the electromagnet used to create the corresponding magnetic field. This may be beneficial, for example, if the orientation of magnetic field lines to which devices 102 and 106 were exposed were particularly important for the test. For example, device 102 may be a magnetic RAM structure that is designed to switch memory states when exposed to a vertically-oriented magnetic field. Device 106, on the other hand, may be an embedded antenna that is required to function normally in its environment even when exposed to a magnetic field of a particular orientation.

Of note, it is also possible to expose either device 102 or 106 to a horizontally-oriented magnetic field line using a solenoid coil, such as solenoid coil 104. For example rotating solenoid coil 104 by 90 degrees may cause field line 118c to pass through device 102 in a largely horizontal orientation. Applying a second solenoid coil to device 106 in a similar fashion may, in some use cases, sufficiently test device 106. Similarly, it is possible to adjust the direction of magnetic field lines 120 at device 106 by adjusting the position of wire 108. For example, by shifting wire 108 to the right and closer to substrate 110, a more vertically-oriented portion of field line 120a may pass through device 106.

Finally, changing the direction of current flow in either solenoid coil 104 or wire 108 could change the direction of the magnetic field lines that intersect devices 102 and 106. For example, by reversing the direction of current flow in solenoid coil 104, magnetic field lines 118a and 118b would flow from the top of device 102 to the bottom of device 102, rather than from the bottom to the top. Further, by reversing the direction of current flow in wire 108, the magnetic field line 120a would flow from the left side of device 106 to the right side of device 106, rather than from the right side to the left side.

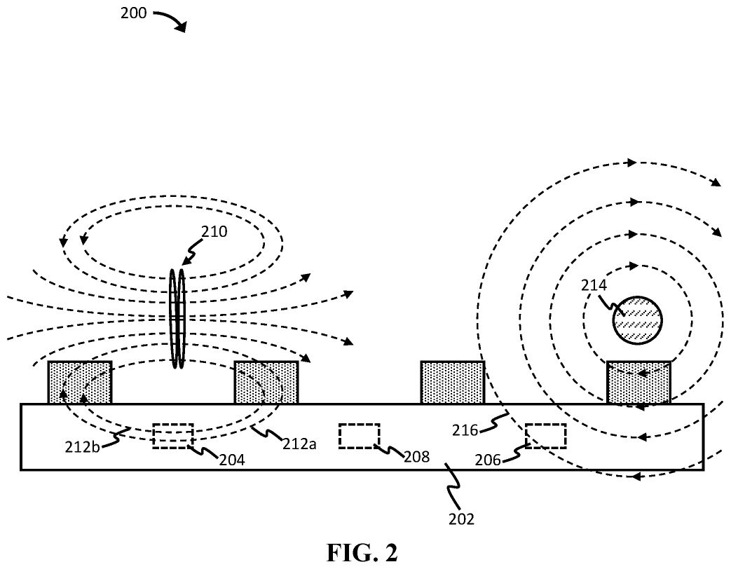

FIG. 2 provides an example of adjusting a position and size of electromagnets in order to adjust the direction of magnetic field lines at a set of test devices. Specifically, FIG. 2 depicts test apparatus 200, in which substrate 202 has been inserted for testing. Substrate 202 contains test devices 204 and 206, as well as sensitive device 208.

Solenoid coil 210 has been positioned directly above device 204 (with respect to apparatus 200) in a vertical orientation, such that magnetic field lines 212a and 212b pass through test device 204 in a largely horizontal direction. Wire 214, on the other hand, has been positioned out of plane from test device 206 with respect to an axis that intersects devices 204-208. In other words, wire 214 is not located in a plane that extends to the top and bottom of FIG. 2, but that extends into and out of the paper on which FIG. 2 is printed and that intersects device 206. This results in magnetic field line 216 passing through test device 206 at approximately a 45-degree angle. Of note, wire 214 may be located farther from device 206 than if wire 214 were placed directly above device 206 (with respect to apparatus 200), which may also result in the strength of the magnetic field at device 206 being weaker. In order to address this side effect, the thickness of wire 214 could be increased, enabling more current to be directed through wire 214, creating a stronger magnetic field.

In some use cases, increasing the current of electricity through a wire can be used to adjust the strength of a magnetic field at a device under test. This may be beneficial, for example, when the same substrate contains multiple devices that require testing at different field strengths.

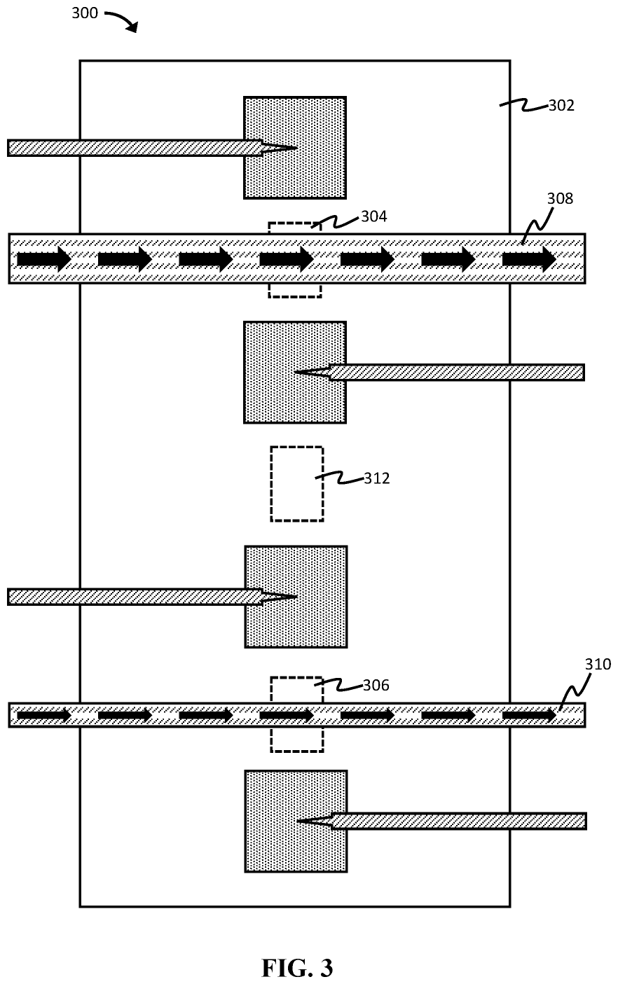

FIG. 3 illustrates a top-down view of an apparatus 300 configured to test a set of devices with multiple magnetic field strengths using wires. Substrate 302, which is inserted into apparatus 300, contains device 304 and 306. It may be necessary to test device 304 with a stronger magnetic field than with device 306. In fact, the strength of the magnetic field required to test device 304 may damage device 306, in some use cases.

For this reason, apparatus 300 incorporates a first wire 308 to test device 304 and a second wire 310 to test device 306. As illustrated, wire 308 is larger than wire 310, and the arrows in wire 308 that signify the direction of current are larger than the arrows in wire 308. Together, these indicate that the current passing through wire 308 is greater than the current that is passing through wire 310. For this reason, if the distance between wire 308 and device 304 is approximately the same as the distance between wire 310 and device 306, the strength of the magnetic field at device 304 should be larger than the strength of the magnetic field at device 306.

While wire 308 is illustrated as thicker than wire 310, a thicker wire is not necessarily needed in order to increase the magnetic field produced by the wire. The magnetic field strength applied to device 304 by wire 308 and to device 306 by wire 310 is a function of the current flowing through the respective wire and the distance between the respective wire and the respective device. Increasing the voltage applied over a wire should, in theory, increase the current that flows through that wire. However, some of the energy from that theoretical current is lost as heat escaping the wire. The amount of current that is lost to heat is proportional to the resistance of the wire, which is affected by the thickness of the wire. Thus, in some instances it may be possible to increase the current flowing through the wire without significantly increasing the percentage of energy lost to heat, but in other instances a thicker wire may be necessary in order to increase current.

However, increasing the strength of a magnetic field to which a test device, such as device 304, is exposed by increasing the strength of the magnetic field produced by a nearby wire, such as wire 308, may also increase the exposure of other nearby devices to that magnetic field. For example, device 312 may be particularly sensitive to magnetic fields, and thus increasing the magnetic field at device 304 by increasing the magnetic field produced by wire 308 may also risk damage to sensitive device 312. In this instance, increasing the strength of the magnetic field exposed to device 304 may be accomplished not by increasing the strength of the magnetic field produced by wire 308, but by decreasing the distance between wire 308 and device 304. For this reason, in some embodiments of the present disclosure, a test apparatus may have the capability to raise and lower wires and solenoid coils further from and closer to the devices under test.

For example, in some embodiments, apparatus 300 may include attachment points for wires 308 and 310 that are located within tracks that are attached to motors. These motors may be capable of translating and rotating the tracks such that the attachment points attached to them are able to shift towards substrate 302 (i.e., into the paper on which FIG. 3 is printed), away from substrate 302 (i.e., out of the paper on which FIG. 3 is printed), towards the top of FIG. 3, or towards the bottom of FIG. 3.

In some embodiments, each attachment point in apparatus 300 may be mounted to a first track, which is itself mounted to a second track that is orthogonal to the first track. For example, the first track may extend into and out of the paper on which FIG. 3 is printed, whereas the second track may extend towards the bottom and top of the paper on which FIG. 3 is printed. Further, the attachment point may be capable of translating throughout the first track (e.g., from one end to the first track to the other end of the first track, or to a point between the first end and the second end), and the first track may be capable of translating throughout the second track. In this embodiment, the attachment point translating on the first track would cause the attachment point to move into and out of the paper on which FIG. 3 is printed. Thus, if wire 310 were secured to the attachment point, this translation would cause wire 310 to move towards and away from device 306. Further, the first track translating on the second track would cause the first track, and thus the attachment point and wire 310, to move towards the top or bottom of the paper on which FIG. 3 is printed (i.e., parallel to substrate 302). This could be used, for example, to shift wire 310 to a position directly above sensitive device 312, rather than directly above device 306.

Further, while not represented in FIG. 3, apparatus 300 may also contain attachment points near the bottom and top of FIG. 3, rather than, or in addition to, on the sides of FIG. 3. With these attachment points, a wire could be capable of spanning the length of apparatus 300 between the top of FIG. 3 to the bottom of FIG. 3. In other words, a single wire could span from the top of FIG. 3 and pass over devices 304, 306, and 312.

Of note, in some embodiments wires 308 and 310 may be entirely independent; for example, wire 308 may be connected to apparatus 300 through a first structural connection (e.g., a first attachment point) and electrically connected to a first current source, whereas wire 310 may be structurally connected to apparatus 300 connected through a second structural connection (e.g., a second attachment point) and electrically connected to a second current source. This may increase the ability to customize the current flowing through each wire and the position of each wire independently. For example, in some embodiments apparatus 300 may be able to shift wire 308 towards or away from device 304 or shift wire 308 towards the top of FIG. 3 or towards the bottom of FIG. 3 (i.e., parallel to substrate 302) without shifting wire 310.

In other embodiments, however, wire 308 and wire 310 may be structurally connected, electrically connected, or both. For example, wire 308 and wire 310 may be part of a single wire loop that is connected to a single current source. In this example, wire 308 and wire 310 may converge (not shown in FIG. 3), forming a single wire to the left of the area shown in FIG. 3 and the right of the area shown in FIG. 3. This single wire may then connect to a current source. In these embodiments, apparatus 300 may still have some ability to adjust the position of the wires independently. For example, by rotating wire 308 towards and away from device 304 around a pivot axis that passes through wire 310, it may be possible for apparatus 300 to decrease or increase the distance between device 304 and wire 308 without affecting the distance between device 306 and wire 310.

As discussed in connection with FIG. 1, some embodiments of this disclosure apply electric fields to a device using solenoid coils, rather than straight wires or wire loops. In these instances, a magnetic field strength applied to a test device can be increased, as discussed with respect to a wire in FIG. 3, by increasing the current flowing through the solenoid coil that produces that magnetic field or by decreasing the distance between that solenoid coil and that test device. However, increasing the strength of a magnetic field could also be performed by increasing the turn density of the wire(s) in the solenoid coil.

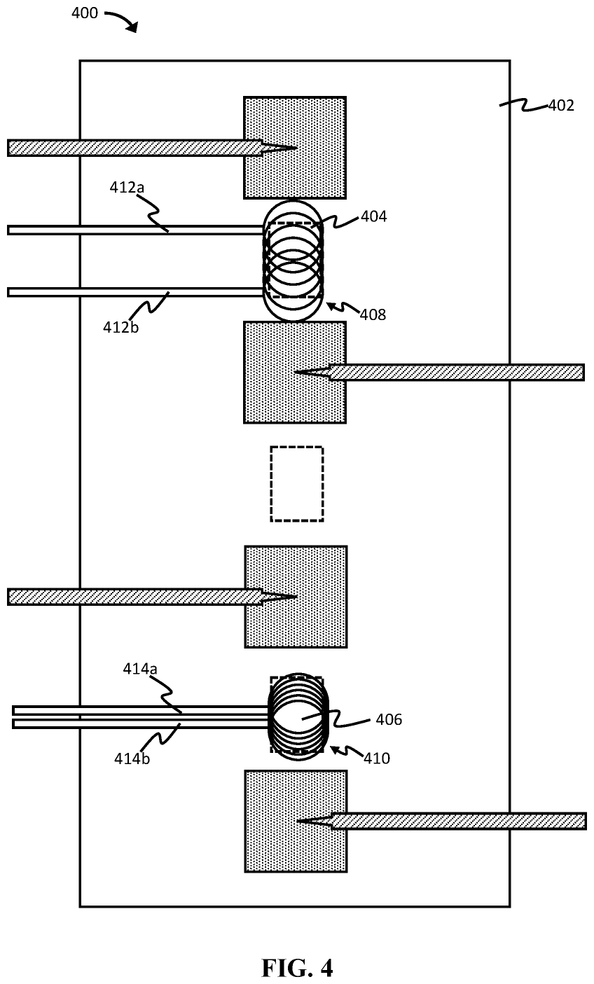

FIG. 4 illustrates a top-down view of an apparatus 400 that comprises solenoid coils of different turn density. Substrate 402, which is inserted into apparatus 400, contains device 404 and 406. It may be necessary to test device 406 with a stronger magnetic field than with device 404. In fact, the strength of the magnetic field required to test device 406 may damage device 404, in some use cases.

In order to expose both devices 404 and 406 to magnetic fields of the appropriate strength, apparatus 400 utilizes solenoid coils 408 and 410, each illustrated as including a coiled wire that completes 6 turns. However, solenoid coil 408 is depicted with a significantly lower turn density than solenoid coil 410. The turn density of a solenoid coil expresses the number of turns that the wire (or wire) in the coil completes per length of the coil itself. For example, if the distance between the top and bottom of solenoid coil 104 in FIG. 1B were 5 mm, the coil density of solenoid coil 104 could be expressed as 2 turns per 5 mm, 1 turn per 2.5 mm, 10 turns per 2.5 cm, etc.

The difference between the turn densities of solenoid coils 408 and 410 is relevant because the turn density of a solenoid coil impacts the strength of the magnetic field created by that coil. Specifically, the strength of the magnetic field produced by the coil increases as the turn density increases. Thus, if the distances between solenoid coils 408 and 410 and their respective test devices are the same (or similar) and the current flowing through the solenoid coils is also the same (or similar), the strength of the magnetic field applied to device 404 by solenoid coil 408 is likely to be significantly weaker than the strength of the magnetic field applied to device 406 by solenoid coil 410.

In some embodiments, apparatus 400 may be able to adjust the strength of the field created by solenoid coils 408 and 410. As discussed previously, adjusting the current that flows through coils 408 and 410 is one method of adjusting their respective magnetic fields. However, apparatus 400 may also be capable of adjusting the coil density of each coil. For example, solenoid coil 408 may be attached to apparatus 400 through solenoid support arms 412a and 412b. In some embodiments, solenoid support arms 412a and 412b may contain a wire that is looped into solenoid coil 408. In some embodiments, solenoid support arms 412a and 412b may contain a wire to which solenoid coil 408 attaches.

Solenoid support arms 412a and 412b may provide a structural connection to apparatus 400, and may also provide a connection to a voltage source within apparatus 400. In some embodiments, the attachment points between apparatus 400 and solenoid support arms 412a and 412b may be adjustable. For example, apparatus 400 may be capable of increasing the distance between a first socket though which solenoid support arm 412a attaches to apparatus 400 and a second socket through which solenoid support arm 412b attaches to apparatus 400. By increasing the distance between solenoid support arms 412a and 412b, the length of solenoid coil 408 may also increase. This may, as a result, decrease the turn density of solenoid coil 408, further decreasing the magnetic field produced by solenoid coil 408.

Alternatively, apparatus 400 may decrease the distance between solenoid support arms 412a and 412b, which may increase the turn density of solenoid coil 408. For example, if apparatus 400 shifts solenoid support arm 412a such that the distance between solenoid support arms 412a equaled the distance between solenoid support arms 414a and 414b, the magnetic fields created by solenoid coils 408 and 410 may be equal. Further, in some embodiments apparatus 400 may be able to adjust the distance between solenoid coil 408 and device 404 and the distance between solenoid coil 410 and device 406 independently. This may increase the ability to apply magnetic fields of the required strengths to each device in a substrate.

This ability to independently raise and lower electromagnets over test devices, as discussed in connection with FIG. 3, may also be beneficial in embodiments such as in FIG. 4 in which solenoid coils are used rather than, or in addition to, wires. For example, solenoid support arms 412a and 412b may be connected through attachment points, to tracks capable of translating and rotating, such that the solenoid coil could shift towards the top of FIG. 4, towards the bottom of FIG. 4, into the page on which FIG. 4 is printed, and out of the page on which FIG. 4 is printed. In some embodiments, the solenoid coil could also be rotated using the attachment point, such that a solenoid coil could be adjusted, for example, from the position shown by coil 410 to the position shown by coil 210 in FIG. 2.

Finally, in some embodiments the lengths of the solenoid support arms may be selected as required to locate the solenoid coil in the desired position with respect to a test device. For example, if device 404 were actually located near the right of FIG. 4, solenoid support arms 412a and 412b may be replaced by longer support arms, causing solenoid coil 408 to extend to the right side of. FIG. 4.

In other embodiments, the lengths of the solenoid support arms, or the attachment points themselves, may be extendable and retractable to enable actively moving the solenoid coil into position. For example, apparatus 400 may be configured to extend or retract solenoid coil 408 to the right or the left, respectively, of FIG. 4 (i.e., parallel to substrate 402) if solenoid support arms 412a and 412b were a telescopic structure. Apparatus 400 may also be configured to extend or retract solenoid support arms 412a and 412b by extending the attachment point(s) to which solenoid support arms are attached.

In some use cases, some substrates may include devices that require testing during exposure to field lines of different directions. To address these use cases, and as discussed in connection to FIGS. 1B and 2, some embodiments of the present disclosure may be capable of applying magnetic field lines of desired directions at different locations of a substrate.

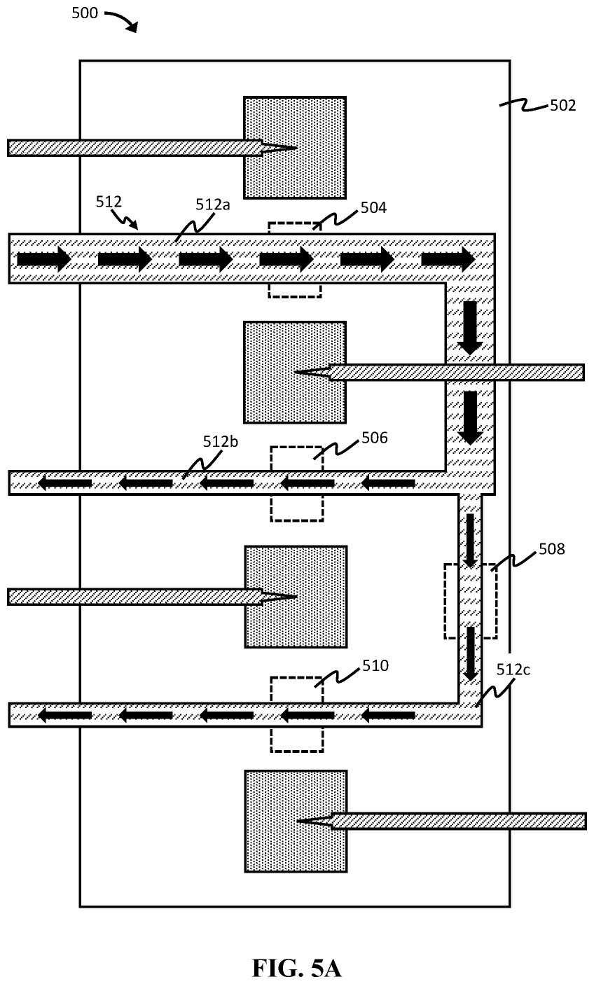

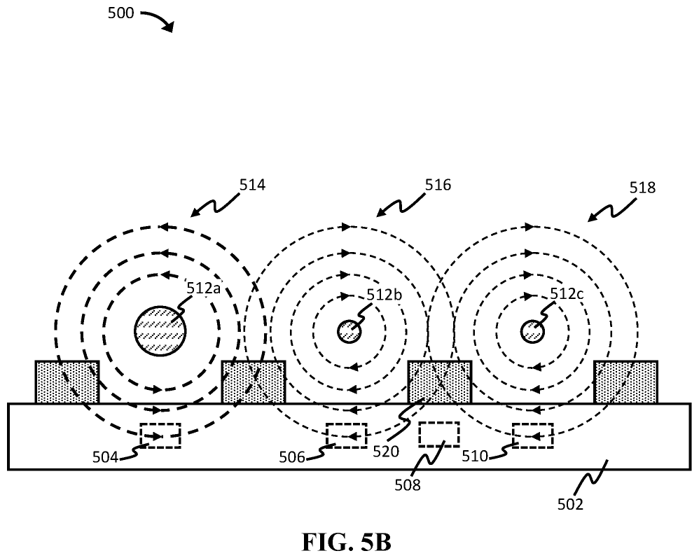

For example, FIG. 5A illustrates a top-down view of an apparatus 500 configured to test four devices in the presence of field lines of various directions. Substrate 502, which is inserted into apparatus 500, contains devices 504, 506, 508, and 510. Device 504 may require testing in the presence of magnetic field lines that proceed from the top of device 504 (as presented in FIG. 5A) to the bottom of device 504 (i.e., from closer to the top of FIG. 5A towards the bottom of FIG. 5A). Devices 506 and 510, however, may require testing in the presence of magnetic field lines that run in the opposite direction (i.e., from closer to the bottom of FIG. 5A towards the top of FIG. 5A). Finally, device 508 may require testing in the presence of magnetic field lines that proceed from closer to the right of FIG. 5A towards the left of FIG. 5A.

To test all of devices 504-510 as required, apparatus 500 includes wire loop 512. The direction of current flowing through wire loop 512 is illustrated with arrows imposed on wire loop 512. In some embodiments, the top, thick section of wire loop 512 (i.e., section 512a; the section that passes over device 504) may originate from a current source in apparatus 500, and the two skinnier sections of wire loop 512 (i.e., section 512b that passes over device 506 and section 512c that passes over devices 508 and 510) may return to that current source, making a complete loop. In other embodiments, the sections 512b and 512c may return to a different point, such as a ground source (e.g., a current receiving terminal).

As illustrated, section 512a is thicker than sections 512b and 512c. Further, section 512a is illustrated with thicker current arrows than sections 512b and 512c. This is to signify that the current flowing through section 512a is greater than the current flowing through section 512b and the current flowing through section 512c.

This is also illustrated in FIG. 5B, which illustrates a side view of FIG. 5A. In FIG. 5B, cross sections of the portions of sections 512a, 512b, and 512c that pass over devices 504, 506, and 508 respectively are shown. The magnetic field created at section 512a is illustrated with field lines 514, the magnetic field created at section 512b is illustrated with field lines 516, and the magnetic field created at section 512c above device 510 is illustrated with field lines 518. The arrows of these field lines depict the direction of the field lines; field lines 514 orbit section 512a in a counter-clockwise direction, whereas field lines 516 and 518 orbit sections 512b and 512c in a clockwise direction. This may be beneficial because field lines 516 and 518 have opposite directions at contact 520. Thus, the net effect magnetic fields on a test probe at contact 520 may be minimized.

Theoretically, the sum of the currents flowing through sections 512b and 512c should equal the current flowing through section 512a. In other words, the current flowing through section 512a is distributed to sections 512b and 512c. The percentage of current that is distributed to each section is dependent upon the relative resistances of those sections, and the relative resistances of those sections can be adjusted by adjusting the relative thicknesses of those sections.

For this reason, by adjusting the relative thicknesses of sections 512b and 512c, the currents flowing through each of these sections can be adjusted. For example, if a wire loop in which section 512b is thicker than section 512c, the current that flows through section 512b should be larger than the current that flows through section 512c. As a result, the magnetic field created around section 512b (and thus the magnetic field applied to device 506) should also be of greater strength than the magnetic field created around section 512c (and thus the magnetic field applied to devices 508 and 510).

For this reason, some embodiments of the present disclosure may include testing apparatuses with the ability to attach wire loops of various shapes and relative thicknesses. Further, in some embodiments, a testing apparatus may be configurable such that multiple straight wires or wire loops, or combinations thereof, may be installed into the testing apparatus at a single time. For example, in some embodiments it may be preferable for a first wire loop to pass over device 504 and 506 and a second wire loop to pass over devices 508 and 512. In some embodiments, it may be preferable for a first wire loop to pass over devices 506, 508, and 510 and a separate, straight wire to pass over device 504. Other arrangements may be possible based on the flexibility of the apparatus and the testing requirements of the devices on a substrate that is installed into that apparatus.

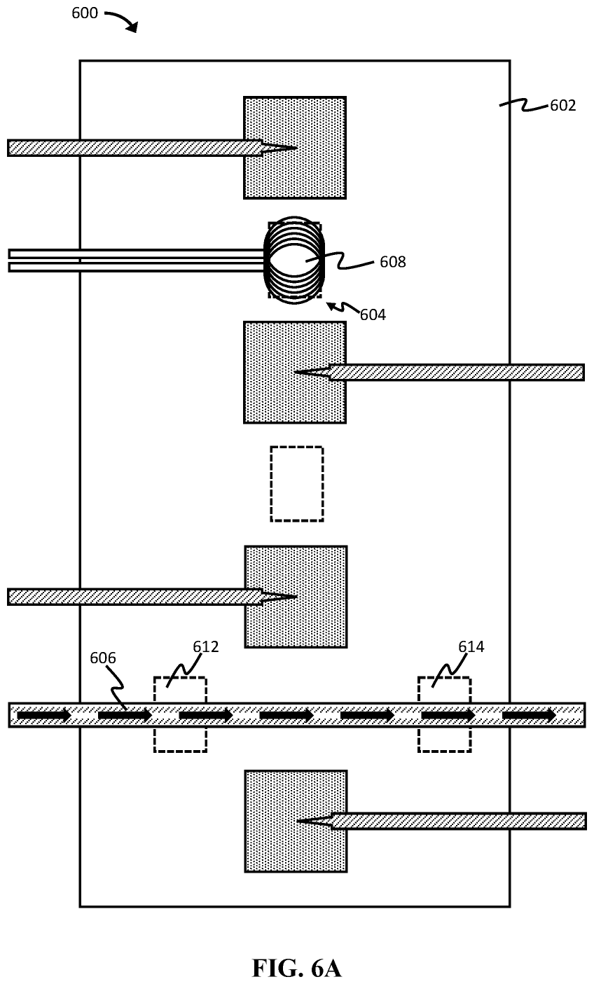

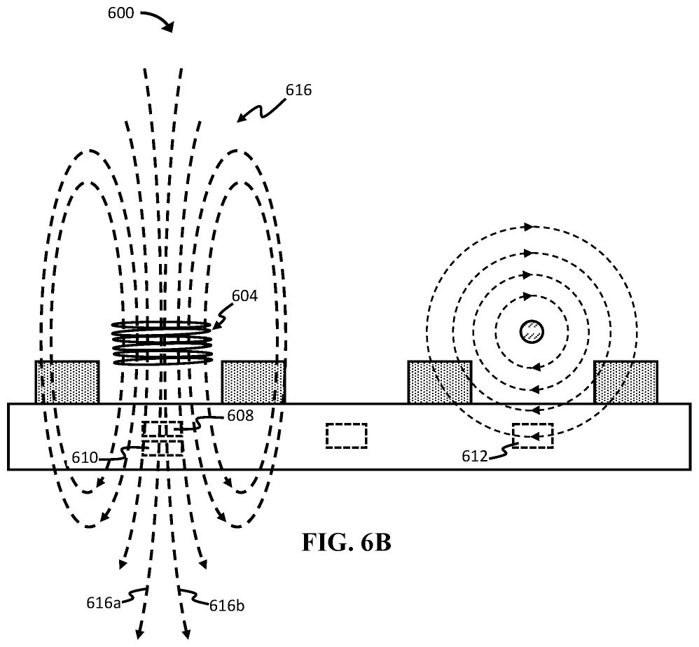

In some use cases one or more devices within a substrate may require testing with magnetic field lines of the same (or approximately the same) direction. Such a set of devices is illustrated within FIGS. 6A and 6B. FIG. 6A illustrates a top-down view of apparatus 600 configured to test two devices with solenoid coil 604 and two devices with wire 606. Specifically, solenoid coil 604 has been placed above device 608 and 610 (device 610 not pictured in FIG. 6A due to being directly beneath device 608), and wire 606 has been placed above device 612 and device 614.

Wire 606 may, in the illustrated configuration, expose devices 612 and 614 to magnetic field lines of extremely similar (if not identical) strengths and directions. This is, in part, because the current flowing through wire 606 above device 612 should be theoretically identical to the current flowing through wire 606 above device 614, and in part because the current flowing through wire 606 is travelling, in aggregate, in the same direction above device 612 as it is above device 614.

Of note, it may also be possible to expose devices 612 and 614 to these identical field lines by configuring identical solenoid coils above each device. For example, two solenoid coils that that are rotated such as coil 210 of FIG. 2 may be capable of producing field lines of the same direction as the field lines produced by wire 606. Thus, in some use cases it may be preferable to configure apparatus 600 with a solenoid coil above device 612 and attached (for example with solenoid support arms) to apparatus 600 on the left side of FIG. 6A, and to configure apparatus 600 with a solenoid coil above device 614 and attached to apparatus 600 on the right side of FIG. 6A. Alternatively, both these solenoid coils may be attached to apparatus 600 at the same point with a shared set of solenoid support arms.

FIG. 6B illustrates a side view of apparatus 600. FIG. 6B illustrates devices 608, 610, and 612, but does not illustrate device 614 due to device 614 being placed directly behind device 612. Solenoid coil 604 may have been configured with a turn density and current that are both high enough to result in field lines 616 that are relatively straight immediately above and below solenoid coil 604. For this reason, the field lines that pass through device 608 (e.g., field lines 616a and 616b) have approximately the same direction as they do when they pass through device 610.

Of note, field lines 616 are illustrated as flowing down through the center of solenoid coil 614 and up through the outside of solenoid coil 604. As a result, the field lines flowing though device 608 and 610 also flow from the top of the devices towards the bottom. Reversing the current flowing through solenoid coil 604 would also reverse the direction of these field lines, enabling devices 608 and 610 to be tested with field lines that both flow down and flow up.

As discussed previously, some embodiments of the present disclosure may feature apparatuses that are customizable in terms of the electromagnets they utilize. For example, it is theoretically possible, though not required, for apparatus 100, 300, 400, 500, and 600 to be the same test apparatus. In these embodiments, it may be possible for electromagnets to be added to and removed from connection points to suit the requirements of the use case. For example, if a substrate contained several devices in a line that required testing with a magnetic field of equal strength and direction, a straight wire that passes over each such device may be inserted into the test apparatus and shifted into position over those several devices. However, if a substrate contained two devices stacked on top of each other that required testing with a magnetic field of equal strength and direction, a solenoid coil may be inserted into the test apparatus instead.

In some embodiments of the present disclosure, a test apparatus may be capable of adjusting the positions and orientations of electromagnets within the test apparatus in order to create a property of a magnetic field that is identified as required for testing a device. For example, if a test apparatus identifies a requirement to test a particular device at a particular location with a particular magnetic field strength, the test apparatus may identify a required position of an electromagnet and a required current to induce in the electromagnet in order to create a magnetic field of that strength at the particular location. The test apparatus may then shift the electromagnet to that required position and induce the required current in the electromagnet.

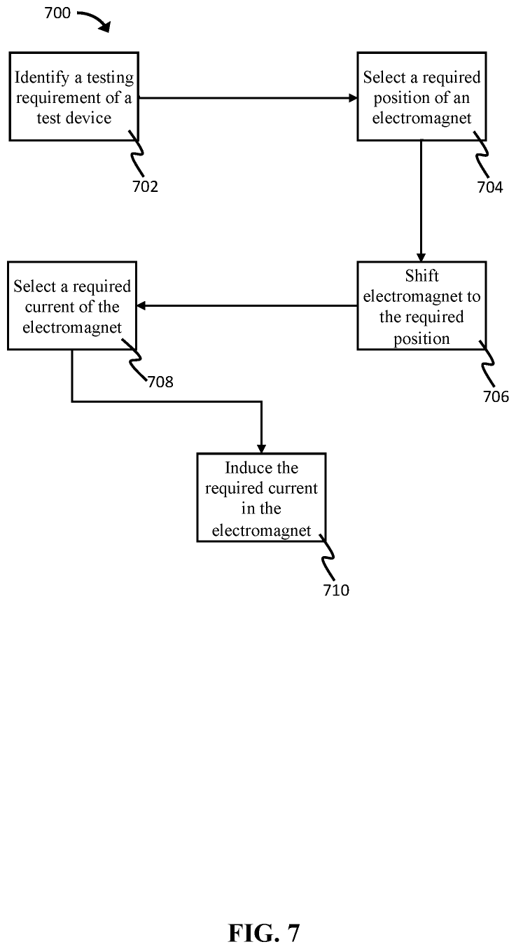

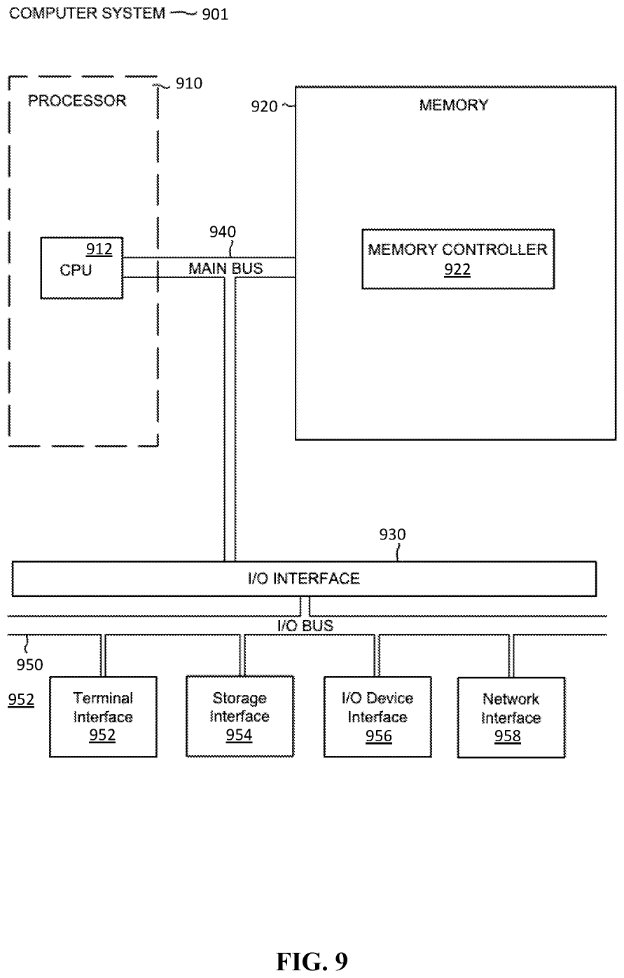

FIG. 7 depicts a method 700 of adjusting a test apparatus based on a testing requirement of a device in the test apparatus. Method 700 may be performed, for example, by a computer system with a processor within the test apparatus, such as computer system 901, depicted in FIG. 9.

FIG. 7 begins at block 702, in which the system identifies a testing requirement of a test device. This testing requirement may comprise a property of a magnetic field to which the test device must be exposed. For example, the testing requirement may include a strength of a magnetic field and a direction of magnetic field lines of the magnetic field.

Once the testing requirement is identified, the system selects a required position of an electromagnet in block 704. This required position may be selected to expose the device to a magnetic field that has the property. For example, if the testing requirement specifies that the test device must be tested with a particularly strong magnetic field, the required position may be relatively close to the test device.

Once the required position is identified, the system shifts the electromagnet to the required position in block 706. This may include, for example, repositioning an attachment point to which the electromagnet is structurally connected. This repositioning may include, for example, translating an attachment point in a first track, translating the first track in a second track, or extending or retracting the attachment point. In some embodiments, shifting the electromagnet may also include rotating the electromagnet into a particular orientation. This may be beneficial, for example, if the electromagnet is a solenoid coil, and the particular orientation would cause field lines of a required direction at the test device.

Method 700 also includes selecting a required current of the electromagnet in block 708. This required current may be selected to expose the test device to a magnetic field that has the property that was identified as part of block 702. For example, if the testing requirement specifies that the test device must be tested with a particularly weak magnetic field (for example, to avoid damage to the device), the required current may be relatively low.

In some embodiments, the required position selected at block 704 and the required current selected at block 708 may be selected together (i.e., based on each other) in order to create a field at the test device that has the property. However, in some embodiments one of the position and current may be selected first. For example, if the required position is selected before the required current, the required current may then be selected based on that required position. In other words, the required current may be selected to create a magnetic field of a particular field strength at the position of the test device based on the distance between the test device and the required position. If the required current is selected before the required position, however, the required position may then be selected based on that required current. In other words, the required position may be selected based on a distance between the test device and the electromagnet that would be required to create to create a magnetic field of a particular field strength at the position of the test device based on the current that will be flowing through the electromagnet.

Once the required current is identified, the system induces the required current in the electromagnet at block 710. This should result in the test device being exposed to a magnetic field that satisfies the testing requirement that was identified in block 702.

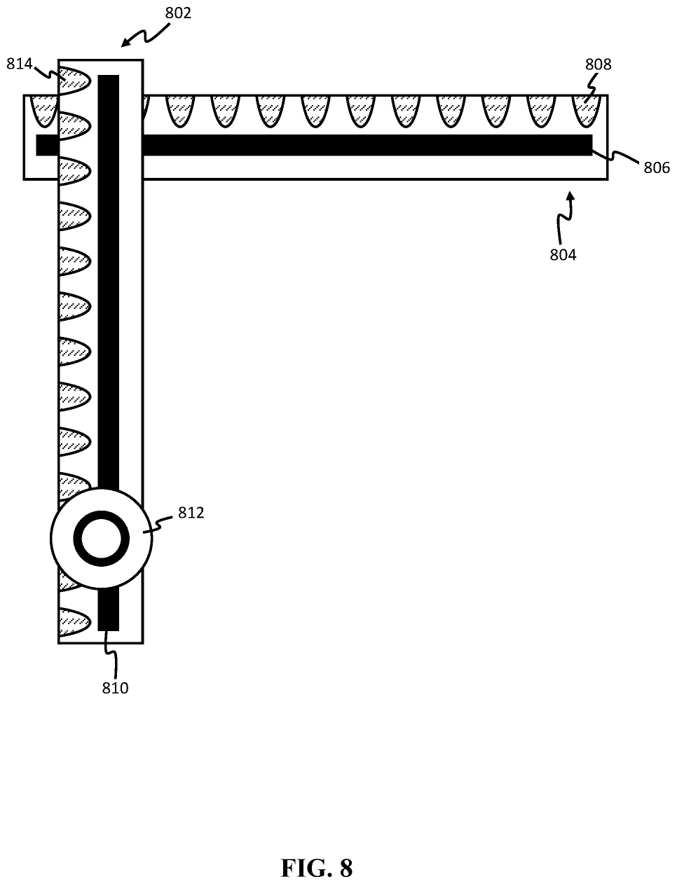

Several embodiments of the present disclosure are described as including a set of tracks that could be used to shift an electromagnet in a test apparatus to a particular location and orientation. For the sake of understanding, FIG. 8 illustrates such a set of tracks. Specifically, FIG. 8 illustrates an example set of tracks by which an electromagnet may be relocated in a test apparatus. Of note, the elements of FIG. 8 are intended to serve as examples only; the specific form and properties of the elements of FIG. 8 are not intended to be limiting. For example, the number and nature of tracks and sub elements thereof may vary without straying from the spirit and scope of the embodiments of this disclosure. Further, different methods of repositioning an attachment point in the testing apparatus aside from multiple tracks may also be implemented without straying from the spirit and scope of the embodiments of this disclosure.

FIG. 8 depicts two tracks 802 and 804. Track 804 contains a gap 806. Track 802 is mounted on track 804 through gap 806 at the point at which the two tracks intersect. For example, the rear side of track 802 may contain a gear with an axel that passes through gap 806 and secures track 802 to the other side of track 804. Track 804 contains a set of gear teeth (e.g., gear tooth 808) with which this teeth on that gear may interface. Thus, when that gear turns, track 802 may translate throughout track 804 (e.g., to the left or right of FIG. 8).

Track 802 also contains a gap 810. Electromagnet attachment point 812 is mounted to track 802 through gap 810. Attachment point 812 may also feature a toothed gear with an axel that passes through gap 812. This toothed gear may interface with gear teeth within track 802 (e.g., gear tooth 814). When this toothed gear rotates, attachment point 812 may translate throughout track 802 (e.g., towards the top and bottom of FIG. 8).

Attachment point 812 may serve as the attachment point for an electromagnet such as a wire loop, a straight wire, or a solenoid coil. Further, attachment point 812 may be configured to rotate that electromagnet. This may be beneficial, for example, to adjust the distance between various sections of a wire loop and a substrate, or for rotating a solenoid coil to different orientations. In some embodiments, attachment point 812 may be capable of mounting multiple solenoid support arms of a solenoid. In other embodiments, multiple attachment points may be mounted on a track, and each attachment point may mount a separate solenoid support arm. This may enable the independent translation of the solenoid support arms in the track, enabling the adjustment of the turn density of the solenoid coil.

FIG. 9 depicts the representative major components of an example Computer System 901 that may be used in accordance with embodiments of the present disclosure. The particular components depicted are presented for the purpose of example only and are not necessarily the only such variations. The Computer System 901 may include a Processor 910, Memory 920, an Input/Output Interface (also referred to herein as I/O or I/O Interface) 930, and a Main Bus 940. The Main Bus 940 may provide communication pathways for the other components of the Computer System 901. In some embodiments, the Main Bus 940 may connect to other components such as a specialized digital signal processor (not depicted).

The Processor 910 of the Computer System 901 may include one or more CPUs 912. The Processor 910 may additionally include one or more memory buffers or caches (not depicted) that provide temporary storage of instructions and data for the CPU 912. The CPU 912 may perform instructions on input provided from the caches or from the Memory 920 and output the result to caches or the Memory 920. The CPU 912 may include one or more circuits configured to perform one or more methods consistent with embodiments of the present disclosure. In some embodiments, the Computer System 901 may contain multiple Processors 910 typical of a relatively large system. In other embodiments, however, the Computer System 901 may contain a single processor with a singular CPU 912.

The Memory 920 of the Computer System 901 may include a Memory Controller 922 and one or more memory modules for temporarily or permanently storing data (not depicted). In some embodiments, the Memory 920 may include a random-access semiconductor memory, storage device, or storage medium (either volatile or non-volatile) for storing data and programs. The Memory Controller 922 may communicate with the Processor 910, facilitating storage and retrieval of information in the memory modules. The Memory Controller 922 may communicate with the I/O Interface 930, facilitating storage and retrieval of input or output in the memory modules. In some embodiments, the memory modules may be dual in-line memory modules.

The I/O Interface 930 may include an I/O Bus 950, a Terminal Interface 952, a Storage Interface 954, an I/O Device Interface 956, and a Network Interface 958. The I/O Interface 930 may connect the Main Bus 940 to the I/O Bus 950. The I/O Interface 930 may direct instructions and data from the Processor 910 and Memory 920 to the various interfaces of the I/O Bus 950. The I/O Interface 930 may also direct instructions and data from the various interfaces of the I/O Bus 950 to the Processor 910 and Memory 920. The various interfaces may include the Terminal Interface 952, the Storage Interface 954, the I/O Device Interface 956, and the Network Interface 958. In some embodiments, the various interfaces may include a subset of the aforementioned interfaces (e.g., an embedded computer system in an industrial application may not include the Terminal Interface 952 and the Storage Interface 954).

Logic modules throughout the Computer System 901—including but not limited to the Memory 920, the Processor 910, and the I/o Interface 930—may communicate failures and changes to one or more components to a hypervisor or operating system (not depicted). The hypervisor or the operating system may allocate the various resources available in the Computer System 901 and track the location of data in Memory 920 and of processes assigned to various CPUs 912. In embodiments that combine or rearrange elements, aspects of the logic modules' capabilities may be combined or redistributed. These variations would be apparent to one skilled in the art.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A testing apparatus comprising:
a first electromagnet configured to expose a first test device to a first electromagnetic field; and
a second electromagnet configured to expose a second test device to a second electromagnetic field.

2. The testing apparatus of claim 1, wherein the first electromagnet is a solenoid coil that is attached to the testing apparatus through an attachment point.

3. The testing apparatus of claim 2, wherein the attachment point is configured to rotate the solenoid coil.

4. The testing apparatus of claim 1, wherein the second electromagnet is a wire that is attached to the testing apparatus through an attachment point.

5. The testing apparatus of claim 4, wherein the wire is a straight wire with a first end that is connected to a current source and a second end that is connected to a ground source.

6. The testing apparatus of claim 4, wherein the wire is a wire loop.

7. The testing apparatus of claim 1, wherein the first electromagnet is attached to the testing apparatus through an attachment point that is mounted on a first track.

8. The testing apparatus of claim 7, wherein translating the attachment point in the first track in a first direction causes the electromagnet to move away from a substrate that contains the first test device.

9. The testing apparatus of claim 7, wherein translating the first track in a second track in a second direction causes the electromagnet to move parallel to a substrate that contains the first test device.

10. A testing-apparatus system comprising:
a processor; and
a memory in communication with the processor, the memory containing program instructions that, when executed by the processor, are configured to cause the processor to perform a method, the method comprising:
identifying a testing requirement of a device, wherein the testing requirement comprises a property of a magnetic field;
selecting a required position of an electromagnet in the testing-apparatus system based on the property, wherein the required position is selected to expose the device to a magnetic field that has the property;
shifting an electromagnet to the required position in the testing-apparatus system;
selecting a required current of the electromagnet, wherein the current is selected to expose the device to the magnetic field that has the property; and
inducing the current in the electromagnet.

11. The testing-apparatus system of claim 10, wherein the electromagnet is mounted to an attachment point within the testing-apparatus system, and the shifting comprises translating the attachment point in a track.

12. The testing-apparatus system of claim 10, wherein shifting the electromagnet comprises rotating the electromagnet.

13. The testing-apparatus system of claim 10, wherein the required property is a strength of the magnetic field.

14. A testing apparatus comprising:
a first track;
a second track mounted on the first track, wherein the second track is oriented orthogonally to the first track and is capable of translating on the first track;
an attachment point mounted on the second track, wherein the attachment point is configured to translate on the second track; and
an electromagnet mounted to the attachment point, such that translating the second track throughout the first track and translating the attachment point throughout the second track causes the electromagnet to change position in the testing apparatus
wherein inducing a current in the electromagnet causes the electromagnet to create a magnetic field in the testing apparatus.

15. The testing apparatus of claim 14, wherein the attachment point is configured to rotate the electromagnet in the testing apparatus.

16. The testing apparatus of claim 14, wherein the electromagnet is a solenoid coil.

17. The testing apparatus of claim 16, wherein the attachment point is configured to extend and retract.

18. The testing apparatus of claim 14, wherein the electromagnet is a wire.

19. The testing apparatus of claim 18, wherein the wire is a wire loop with a first section that has a first thickness and a second section that has a second thickness that is different than the first thickness.

20. The testing apparatus of claim 18, wherein the wire is a wire loop, and wherein the wire loop is configured such that the magnetic field exposes a first test device to a first magnetic field line in a first direction and exposes a second test device to a second magnetic field line in a second direction.
